(19) United States
(12) Patent Application Publication
(10) Pub. No.: US 2026/0372216 A1
(43) Pub. Date: Nov. 19, 2026

(54) SEMICONDUCTOR PACKAGES AND METHODS OF FORMING THE SAME

(71) Applicant: Taiwan Semiconductor Manufacturing Company, Ltd., Hsinchu (TW)

(72) Inventors: Chen-Hsuan Tsai, Taitung City (TW); Chin-Chuan Chang, Hsinchu County (TW)

(73) Assignee: Taiwan Semiconductor Manufacturing Company, Ltd., Hsinchu (TW)

(21) Appl. No.: 19/754,239

(22) Filed: Jul. 26, 2026

Related U.S. Application Data
(62) Division of application No. 18/480,526, filed on Oct. 4, 2023.

(51) Int. Cl. H10W 90/00; G02B 6/12; G02B 6/42; H10P 72/70; H10W 72/20; H10W 72/90; H10W 74/00; H10W 74/01; H10W 74/10; H10W 74/15

(52) U.S. Cl. CPC H10W 90/701; G02B 6/12004; G02B 6/4293; H10P 72/74; H10W 74/012; H10W 74/15; H10W 90/00; G02B 2006/12038; G02B 2006/12147; H10W 72/244; H10W 72/252; H10W 72/9226; H10W 72/923; H10W 72/942; H10W 74/00; H10W 74/142

(57) ABSTRACT

A method of forming a semiconductor package includes the following operations. At least one integrated circuit structure is provided and bonded to an interposer structure. A photonic structure is provided and bonded to the interposer structure, wherein the photonic structure has a recessed feature covered by a mask and facing a light source. An encapsulation layer is formed around the at least one integrated circuit structure and the photonic structure. At least a portion of the mask layer is removed from the photonic structure.

### CROSS-REFERENCE TO RELATED APPLICATION

This is a divisional application of and claims the priority benefit of U.S. application Ser. No. 18/480,526, filed on Oct. 4, 2023, now pending. The entirety of the above-mentioned patent application is hereby incorporated by reference herein and made a part of this specification.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing semiconductor packages have been generally adequate for their intended purposes, they have not been entirely satisfactory in all respects.

### BRIEF DESCRIPTION OF THE DRAWINGS

FIG. 1 to FIG. 7 are schematic cross-sectional views of a method of forming a semiconductor package in accordance with some embodiments.

FIG. 8 to FIG. 14 are schematic cross-sectional views of a method of forming a semiconductor package in accordance with some embodiments.

FIG. 15 to FIG. 21 are schematic cross-sectional views of a method of forming a semiconductor package in accordance with some embodiments.

FIG. 22 to FIG. 28 are schematic cross-sectional views of a method of forming a semiconductor package in accordance with some embodiments.

FIG. 29 illustrates a method of forming a semiconductor package in accordance with some embodiments.

FIG. 30 illustrates a method of forming a semiconductor package in accordance with some embodiments.

### DETAILED DESCRIPTION

The following disclosure provides many different embodiments, or examples, for implementing different features of the provided subject matter. Specific examples of components and arrangements are described below for the purposes of conveying the present disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same reference numerals and/or letters may be used to refer to the same or similar parts in the various examples the present disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose semiconductor packages such as photonic-electric integrated circuit (IC) packages. With the method of the disclosure, a photonic device and other system and memory devices can be easily integrated together in a wafer level platform. With optical interconnection provided by the photonic structure, higher communication performance and more compact packaging can be easily achieved.

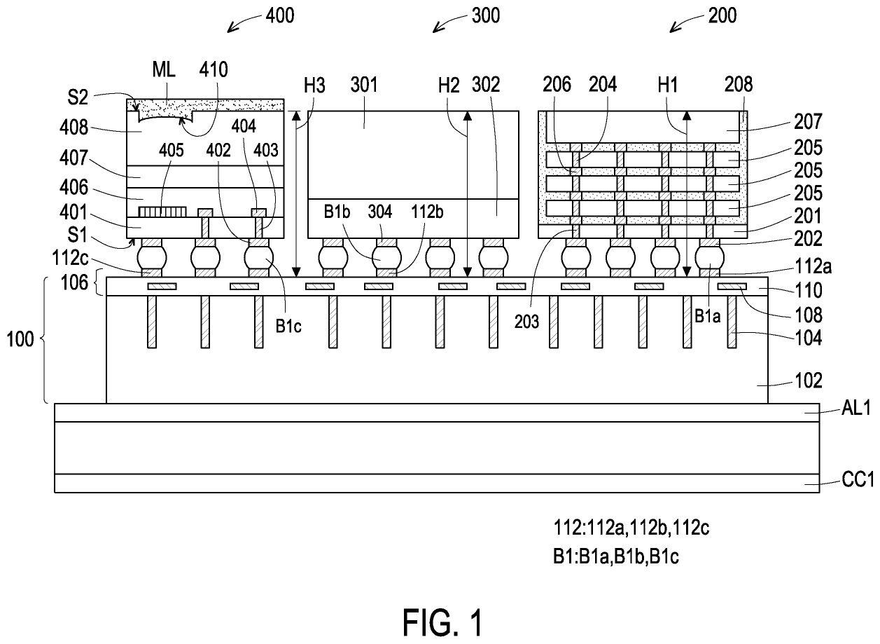

FIG. 1 to FIG. 7 are schematic cross-sectional views of a method of forming a semiconductor package in accordance with some embodiments. It is understood that the disclosure is not limited by the method described below. Additional operations can be provided before, during, and/or after the method and some of the operations described below can be replaced or eliminated, for additional embodiments of the methods. Although FIG. 1 to FIG. 7 are described in relation to a method, it is appreciated that the structures disclosed in FIG. 1 to FIG. 7 are not limited to such a method, but instead may stand alone as structures independent of the method.

Referring to FIG. 1, an interposer structure 100 is attached to a carrier CC1. In some embodiments, the carrier CC1 includes a glass carrier or a suitable carrier. In some embodiments, the interposer structure 100 is attached to the carrier CC1 through an adhesive layer AL1. The adhesive layer AL1 may include an oxide layer, a die attach tape (DAF) or a suitable adhesive.

In some embodiments, the interposer structure 100 includes a substrate 102, through substrate vias 104 and a conductive structure 106. The substrate 102 may include elementary semiconductor such as silicon, germanium and/or a compound semiconductor such as silicon germanium, silicon carbide, gallium arsenic, indium arsenide, gallium nitride or indium phosphide. The substrate 102 may be doped as needed. The through substrate vias 104 (also called “through silicon vias” in some examples) extend from a first side (e.g., front side) of the substrate 102 towards a second side (e.g., back side) of the substrate 102. The through substrate vias 104 may not penetrate through the substrate 102 at this stage.

In some embodiments, the conductive structure 106 is disposed over the front side of the substrate 102 and electrically connected to the through substrate vias 104. In some embodiments, the conductive structure 106 includes conductive features 108 embedded by dielectric layers 110. The conductive features 108 include metal lines, metal vias, metal pads and/or metal connectors. In some embodiments, each conductive feature 108 includes Cu, Al, Ti, Ta, W, Ru, Co, Ni, the like, or a combination thereof. In some embodiments, a seed layer and/or a barrier layer may be disposed between each conductive feature and the adjacent polymer layer. The seed layer may include Ti/Cu. The barrier layer may include Ta, TaN, Ti, TiN, CoW or a combination thereof. In some embodiments, each dielectric layer includes silicon oxide, silicon nitride, silicon oxynitirde, silicon oxycarbide, the like, or a combination thereof. An etching stop layer may be interposed between two adjacent dielectric layers. The dielectric layers of the conductive structure 106 may be replaced by polymer layers or insulating layers as needed. Each polymer layer may include polybenzoxazole (PBO), polyimide (PI), benzocyclobutene (BCB), the like, or a combination thereof.

In some embodiments, the critical dimension (e.g. line width or via width) of the conductive structure 106 close to the substrate 102 is different from (e.g., less than) the critical dimension (e.g. line width or via width) of the conductive structure 106 away from the substrate 102. In some embodiments, the conductive structure 106 further includes metal pads 112 configured to electrically connected to the overlying electrical components, semiconductor devices or integrated circuit structures. The metal pads 112 may be divided into different groups of metal pads 112a, 112b and 112c for different electrical components, semiconductor devices or integrated circuit structures.

In some embodiments, the interposer structure 100 is an active interposer that contains at least one functional device or integrated circuit device included in the conductive structure 106. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer structure 100 is a passive interposer, which is used to convey a lack of a functional device or integrated circuit device. Such passive interposer is referred to as a “device-free interposer” in some examples.

Still referring to FIG. 1, an integrated circuit structure 200 is provided and bonded to the interposer structure 100. The integrated circuit structure 200 may be a memory device such as a dynamic random-access memory (DRAM), a synchronous dynamic random-access memory (SDRAM), a die stack such as a high bandwidth memory (HBM) cube, or the like. In some embodiments, the integrated circuit structure 200 (e.g., memory device) includes, for example, a bottom die 202, multiple inner dies 205 and a top die 207. The bottom die 202 may be a silicon interposer including through silicon vias 202 therein. The inner dies 205 may be memory dies including through silicon vias 206 therein. The top die 207 may be a controller die or a core die, and may be free of through silicon vias. The inner dies 205 are electrically connected to each other and electrically connected to the bottom die 202 and the top die 207 through connectors 206. In some embodiments, the width of the bottom die 202 is greater than the widths of the inner dies 205 and top die 207. In some embodiments, the top die 207 is thicker than the inner dies 205.

In some embodiments, the integrated circuit structure 200 (e.g., memory device) further includes an encapsulation layer 208 over the bottom die 202 and laterally encapsulating the inner des 205 and the top die 207. In some embodiments, the encapsulation layer 208 includes a molding compound, a molding underfill, a resin or the like. In some embodiments, the encapsulation layer 208 includes a polymer material such as polybenzoxazole (PBO), polyimide, benzocyclobutene (BCB), the like, or a combination thereof. The encapsulation layer 208 may be formed by a molding process followed by a curing process.

In some embodiments, the integrated circuit structure 200 (e.g., memory device) further includes metal pads 202 configured to electrically connected to the underlying electrical component, semiconductor device or integrated circuit structure. Specifically, the integrated circuit structure 200 (e.g., memory device) is bonded to the interposer structure 100 through the metal pads 202, bumps B1a and the metal pads 112a. The bumps B1a may be formed over the metal pads 202, the metal pads 112a or both. In some embodiments, the bumps B1a include solder bumps, and/or may include metal pillars (e.g., copper pillars), solder caps formed on metal pillars, and/or the like. The bumps B1a are referred to as “micro bumps” in some examples. The bumps B1a may be formed by a suitable process such as evaporation, electroplating, ball drop, or screen printing.

Still referring to FIG. 1, an integrated circuit structure 300 is provided and bonded to the interposer structure 100. The integrated circuit structure 300 may be a system device such as application-specific integrated circuit (ASIC), a field programmable gate array (FPGA), a central processing unit (CPU) die, a graphics processing unit (GPU) die, an artificial intelligence (AI) engine die, a transceiver (TRX) die, or the like. In some embodiments, the integrated circuit structure 300 (e.g., system device) includes a substrate 301 and a device layer 302. The substrate 301 may include elementary semiconductor such as silicon, germanium and/or a compound semiconductor such as silicon germanium, silicon carbide, gallium arsenic, indium arsenide, gallium nitride or indium phosphide. The substrate 301 may be doped as needed. The device layer 302 may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer 302 may further include an interconnect structure electrically connected to the transistor.

In some embodiments, the integrated circuit structure 300 (e.g., system device) further includes metal pads 304 configured to electrically connected to the underlying electrical component, semiconductor devices or integrated circuit structure. Specifically, the integrated circuit structure 300 (e.g., system device) is bonded to the interposer structure 100 through the metal pads 304, bumps B1b and the metal pads 112b. The bumps B1b may be formed over the metal pads 202, the metal pads 112b or both. In some embodiments, the bumps B1b include solder bumps, and/or may include metal pillars (e.g., copper pillars), solder caps formed on metal pillars, and/or the like. The bumps B1b are referred to as “micro bumps” in some examples. The bumps B1b may be formed by a suitable process such as evaporation, electroplating, ball drop, or screen printing.

Still referring to FIG. 1, a photonic structure 400 is provided and bonded to the interposer structure 100. In some embodiments, the photonic structure includes a first substrate 401 and a second substrate 408 bonded to each other. Each of the first substrate 401 and the second substrate 408 may include elementary semiconductor such as silicon, germanium and/or a compound semiconductor such as silicon germanium, silicon carbide, gallium arsenic, indium arsenide, gallium nitride or indium phosphide. Each of the first substrate 401 and the second substrate 408 may be doped as needed. In some embodiments, the first substrate 401 may include a doped silicon substrate, and the second substrate 408 may be a bare silicon substrate. The first substrate 401 is referred to as a “photonic die” and the second substrate 408 is referred to as a “support die” in some examples.

In some embodiments, the first substrate 401 of the photonic structure 400 may include a photonic integrated circuit (PIC) for providing photonic function and optionally an electrical integrated circuit (EIC) for providing electrical function, and such photonic structure 400 may be referred to as a silicon photonic (SiPh) structure in some examples. In some embodiments, the first substrate 401 includes through silicon vias 403 and metal pads 404 configured to electrically connected to the photonic integrated circuit. In some embodiments, the first substrate 401 further includes metal pads 402 at a surface S1 thereof, and the metal pads 402 are configured to electrically connected to the underlying electrical components, semiconductor devices or integrated circuit structures.

In some embodiments, the first substrate 401 further includes an integrated optical device 405 such as a grating coupler or a waveguide coupler. The grating coupler is configured to enable communication between a light source and another component (e.g., photo-detector). For example, an optical grating coupler can be used to redirect light from an optical fiber into an optical detector.

In some embodiments, the first substrate 401 further includes a first passivation layer 406 covering the integrated optical device 405 and the metal pads 404. The passivation layer 406 includes a dielectric layer such as silicon oxide, silicon nitride, silicon oxynitirde, silicon oxycarbide, the like, or a combination thereof. The dielectric layer may be replaced by a polymer layer or an insulating layer as needed. The polymer layer may include polybenzoxazole (PBO), polyimide (PI), benzocyclobutene (BCB), the like, or a combination thereof. The first passivation layer 406 is referred to a “first cladding layer” in some examples.

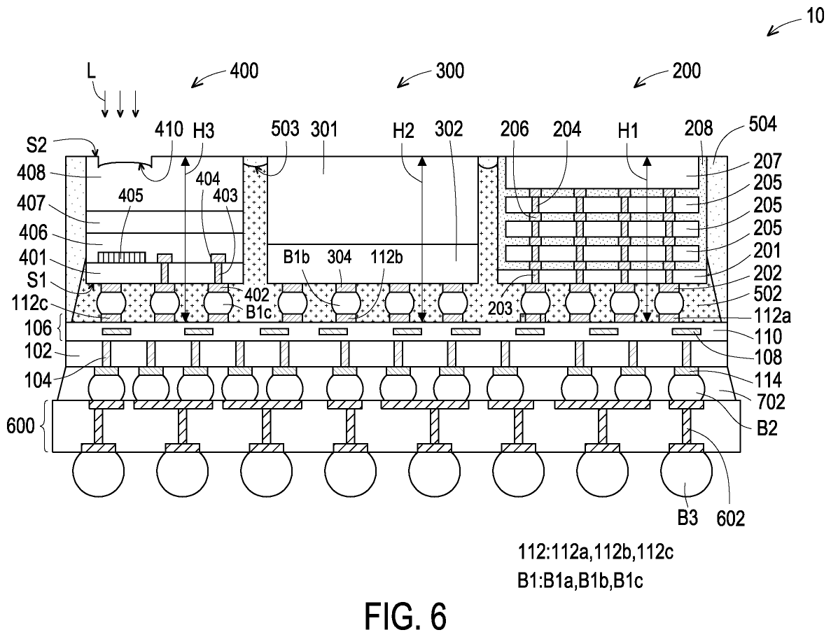

In some embodiments, the second substrate 408 of the photonic structure 400 includes a recessed feature 410 at a surface S2 thereof, and the recessed feature 410 faces a light source (as shown in FIG. 6). The recessed feature 410 may be referred to as an “optical recessed feature” in some examples. The recessed feature 410 may be an optical recessed lens, for example. In some embodiments, the recessed feature 410 has a substantially vertical sidewall and a convex bottom. The recessed feature 410 may be designed to have desired curvature for focusing the light beam to the underlying integrated optical device 405. In some embodiments, the recessed feature 410 is aligned with the underlying integrated optical device 405, but the disclosure is not limited thereto. In other embodiments, the recessed feature 410 may be misaligned with or partially overlapped with the underlying integrated optical device 405.

Still referring to FIG. 1, the recessed feature 410 is covered and protected by a mask layer ML at this stage, and the mask layer ML is completely removed in the later stage, which will be described in details below. The mask layer ML includes any removable material, and such removable material may be transparent, translucent or opaque. In some embodiments, the mask layer ML includes a dielectric layer such as silicon oxide, silicon nitride, silicon oxynitirde, silicon oxycarbide, or the like, and is formed by a suitable deposition process such as chemical vapor deposition process. In some embodiments, the mask layer ML includes a polymer layer such as polybenzoxazole (PBO), polyimide (PI), benzocyclobutene (BCB), or the like, and is formed by a coating process or a laminating process. In some embodiments, the mask layer ML includes a molding compound such as epoxy, and is formed using dispensing, injecting, and/or spraying process. The mask layer ML may be subjected to a planarization, so as to have a planar surface. In some embodiments, the mask layer ML covers the entire surface S2 of the photonic device 400 and fills the recessed feature 410. However, the disclosure is not limited thereto. In other embodiments, the mask layer may cover a portion of the surface S2 of the photonic device 400 and fills the recessed feature 410.

In some embodiments, the second substrate 408 further includes a second passivation layer 407 on a surface opposite to the recessed feature 410. The passivation layer 407 includes a dielectric layer such as silicon oxide, silicon nitride, silicon oxynitirde, silicon oxycarbide, the like, or a combination thereof. The dielectric layer may be replaced by a polymer layer or an insulating layer as needed. The polymer layer may include polybenzoxazole (PBO), polyimide (PI), benzocyclobutene (BCB), the like, or a combination thereof. The second passivation layer 407 is referred to a “second cladding layer” in some examples.

In some embodiments, the first substrate 401 having an integrated optical device 405 is bonded to the second substrate 408 having a recessed feature 410 through the first passivation layer 406 and the second passivation layer 407. However, the disclosure is not limited thereto. In other embodiments, the first substrate 401 may be bonded to the second substrate 408 through another suitable bonding method. In some embodiments, light signals from a light source may be coupled to the recessed feature 410 (e.g., optical recessed lens), which directs the light signals through the second substrate 408, the second passivation layer 407, the first passivation layer 406 and then to the integrated optical device 405 (e.g., grating coupler).

In some embodiments, the photonic structure 400 is bonded to the interposer structure 100 through the metal pads 402, bumps B1c and the metal pads 112c. The bumps B1c may be formed over the metal pads 402, the metal pads 112c or both. In some embodiments, the bumps B1c include solder bumps, and/or may include metal pillars (e.g., copper pillars), solder caps formed on metal pillars, and/or the like. The bumps B1c are referred to as “micro bumps” in some examples. The bumps B1c may be formed by a suitable process such as evaporation, electroplating, ball drop, or screen printing.

In some embodiments, as shown in FIG. 1, the height H3 of the photonic structure is substantially the same as the height H1 of the integrated circuit structure 200 or the height H2 of the integrated circuit structure, counting from the surface of the interposer structure 100. However, the disclosure is not limited thereto. In other embodiments, the height H3 of the photonic structure may be different from (e.g., less than) the height H1 of the integrated circuit structure 200 or the height H2 of the integrated circuit structure, counting from the surface of the interposer structure 100.

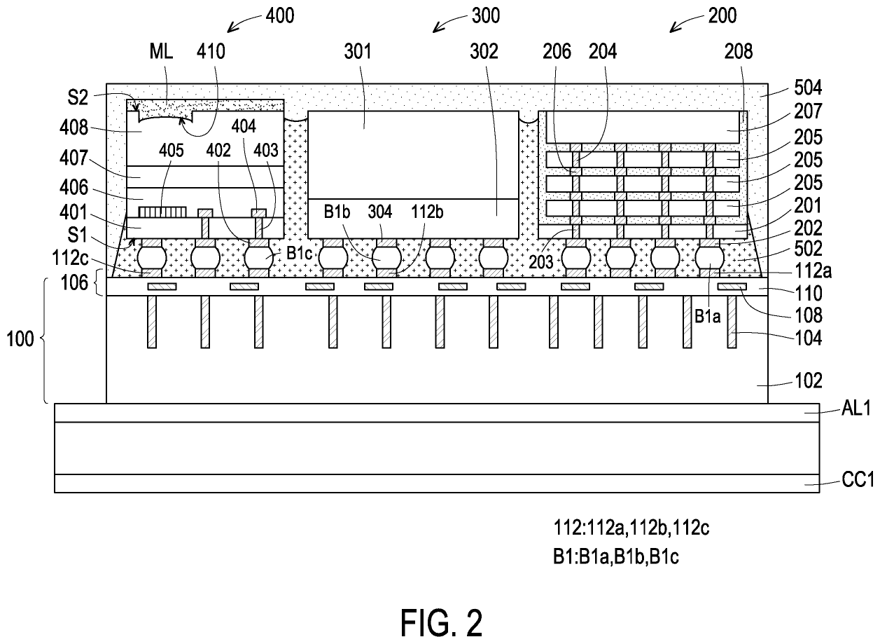

Referring to FIG. 2, an underfill layer 502 is formed to fill the space between the interposer structure 100 and each of the integrated circuit structures 200, 300 and the photonic structure 400, and surrounds the bumps B1 including bumps B1a, B1b and B1c. In some embodiments, the underfill layer 502 partially fills the gap between the integrated circuit structures 200 and 300 and the gap between the integrated circuit structure 300 and the photonic structure 400. In some embodiments, the underfill layer 502 includes a molding compound such as epoxy, and is formed using dispensing, injecting, and/or spraying process. The underfill layer 502 between two adjacent structure may have a curve and concave surface.

Thereafter, an encapsulation layer 504 is formed over the interposer structure 100 and covers the integrated circuit structures 200, 300 and the photonic structure 400. In some embodiments, the encapsulation layer 504 is formed over the underfill layer 502 and completely fills the gap between the integrated circuit structures 200 and 300 and the gap between the integrated circuit structure 300 and the photonic structure 400. Specifically, the encapsulation layer 504 covers tops of the integrated circuit structures 200, 300, encapsulates the sidewalls (uncover by the underfill layer 502) of the integrated circuit structures 200, 300 and the photonic structure 400, and covers the exposed surface of the mask layer ML. In some embodiments, the encapsulation layer 504 includes a molding compound, a molding underfill, a resin or the like. In some embodiments, the encapsulation layer 504 includes a polymer material such as polybenzoxazole (PBO), polyimide, benzocyclobutene (BCB), the like, or a combination thereof. The encapsulation layer 504 may be formed by a molding process followed by a curing process.

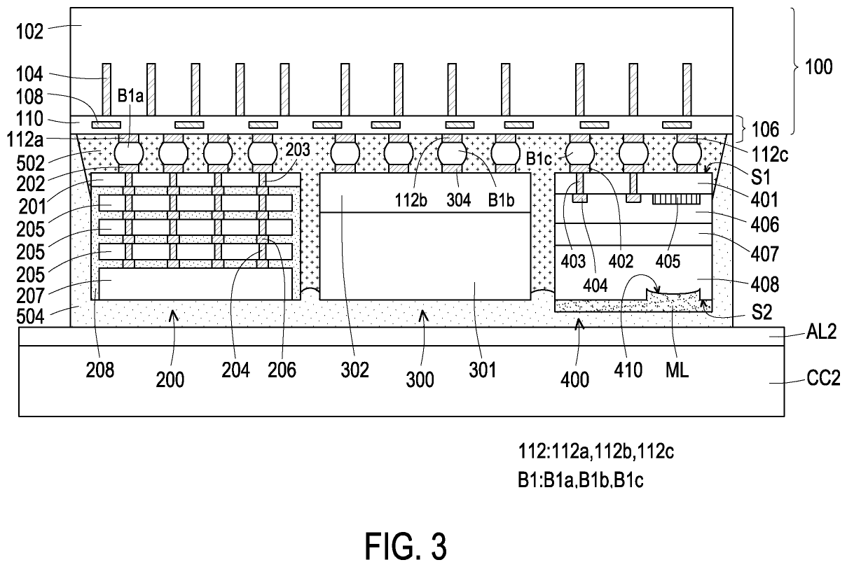

Referring to FIG. 3, a carrier CC2 is attached to the encapsulation layer 504. In some embodiments, the carrier CC2 includes a glass carrier or a suitable carrier. In some embodiments, the carrier CC2 is attached to the encapsulation layer 504 through an adhesive layer AL2. The adhesive layer AL2 may include an oxide layer, a die attach tape (DAF) or a suitable adhesive.

Thereafter, the structure with the carrier CC2 is flipped over, and the carrier CC1 is debonded from the structure. In one embodiment, the debonding process is a laser debonding process or a suitable process. The adhesive layer AL1 is removed from the interposer structure 100. In some embodiments, the removing process is an etching process and/or a cleaning process.

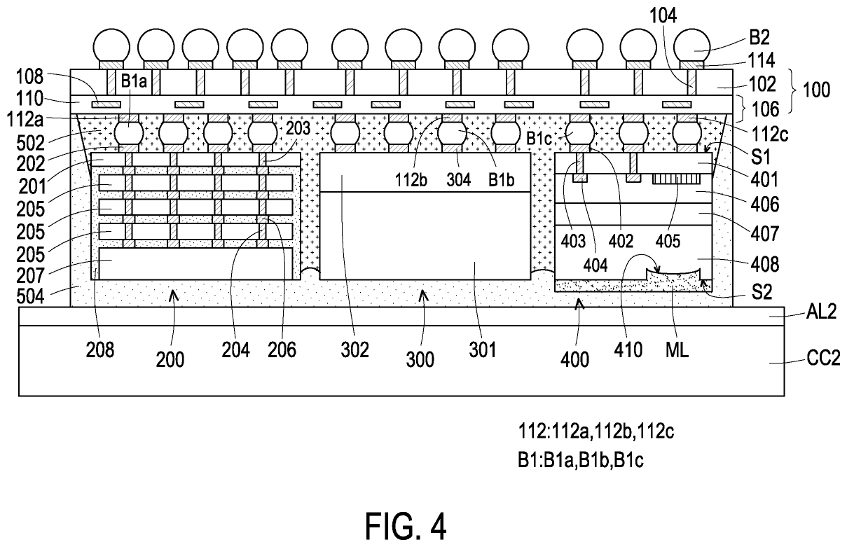

Referring to FIG. 4, a polishing process is performed to the interposer structure 100, until the through substrate vias 104 are exposed. In some embodiments, a chemical mechanical polishing (CMP) process is performed to thin the substrate 102 and the through substrate vias 104 of the interposer structure 100. In some embodiments, metal pads 114 (or called under ball metallizaton pads) are formed over and electrically connected to the through substrate vias 104. Afterwards, bumps B2 are formed over and electrically connected to the metal pads 114. In some embodiments, the bumps B2 include solder bumps, and/or may include metal pillars (e.g., copper pillars), solder caps formed on metal pillars, and/or the like. The bumps B2 are referred to as “controlled collapse chip connection (C4) bumps” in some examples. The bumps B2 may be formed by a suitable process such as evaporation, electroplating, ball drop, or screen printing. The size of the bumps B2 may be different from (e.g., greater than) the size of the bumps B1.

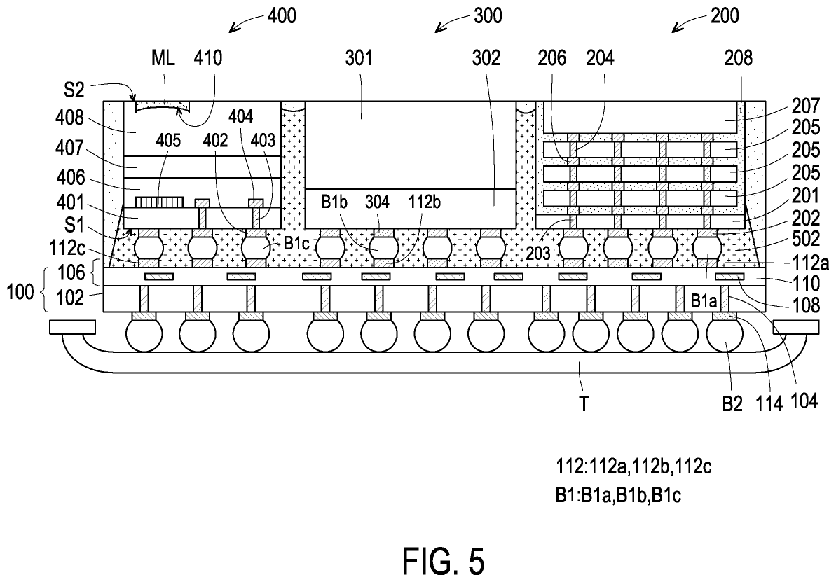

Referring to FIG. 5, the structure of FIG. 4 is flipped over and attached to a wafer tape T, with the bumps B2 facing the wafer tape T. In some embodiments, the wafer tape T includes PVC, polyolefin, polyethylene, or other suitable materials.

Thereafter, the carrier CC2 is debonded from the encapsulation layer 504. In one embodiment, the debonding process is a laser debonding process or a suitable process. The adhesive layer AL2 is then removed from the encapsulation layer 504. In some embodiments, the removing process is an etching process and/or a cleaning process.

Afterwards, a grinding process is performed to the encapsulation layer 504. In some embodiments, the grinding process further partially removes the mask layer ML, until the surface S2 of photonic device 400 is exposed. In some embodiments, upon the grinding process, the top surface of the encapsulation layer 504 is substantially coplanar with or flushed with the top surface of the remaining mask layer ML as well as the top surfaces of the integrated circuit structures 200, 300 and the photonic structure 400.

Referring to FIG. 6, the mask layer ML is removed from the recessed feature 410 of the photonic structure 400. In some embodiments, the mask layer ML is completely removed by an etching process, a plasma process, a laser process, the like, or a combination thereof. Upon the removing process, the recessed feature 410 as an optical recessed lens is exposed to the external environment, facing to a light source L.

In some embodiments, a wafer dicing process is performed, so as to separate adjacent structures from each other. Thereafter, the wafer tape T is removed, and a board substrate 600 is formed below and electrically connected to the interposer structure 100. In some embodiments, the board substrate 600 is bonded to the interposer structure 100 through the bumps B2.

In some embodiments, the board substrate 600 includes a core layer and two build-up layers on opposite sides of the core layer. In some embodiments, the core layer includes prepreg (which contains epoxy, resin, and/or glass fiber), polyimide, photo image dielectric (PID), the like, or a combination thereof. In some embodiments, the build-up layers include prepreg (which contains epoxy, resin, and/or glass fiber), polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), the like, or a combination thereof. The material of the core layer may be different from the material of the build-up layers. In some embodiments, the board substrate 600 includes wiring patterns 602 that penetrate through the core layer and the build-up layers for providing electrical routing between different interposers, dies or die stacks. The wiring patterns 602 include lines, vias, pads and/or connectors. The board substrate 600 is referred to as a “printed circuit board (PCB)” in some examples. In other embodiments, the core layer of the board substrate 600 may be omitted as needed, and such board substrate 600 is referred to as a “coreless board substrate”.

Thereafter, an underfill layer 702 is formed to fill the space between the interposer structure 100 and the board substrate 600, and surrounds the bumps B2. In some embodiments, the underfill layer 702 includes a molding compound such as epoxy, and is formed using dispensing, injecting, and/or spraying process.

Afterwards, bumps B3 are formed below and electrically connected to the board substrate 600. In some embodiments, bump B3 are electrically to the wiring patterns 602 of the board substrate 600. In some embodiments, the bumps B3 include solder bumps, and/or may include metal pillars (e.g., copper pillars), solder caps formed on metal pillars, and/or the like. The bumps B3 are referred to as “ball grid array (BGA) balls” in some examples. The bumps B3 may be formed by a suitable process such as evaporation, electroplating, ball drop, or screen printing. The size of the bumps B3 may be different from (e.g., greater than) the size of the bumps B2. In some embodiments, the semiconductor package 10 of the disclosure is thus completed. With the method of the disclosure, a photonic device and other system and memory devices can be easily integrated together in a wafer level platform. With optical interconnection provided by the photonic structure, higher communication performance and more compact packaging can be easily achieved.

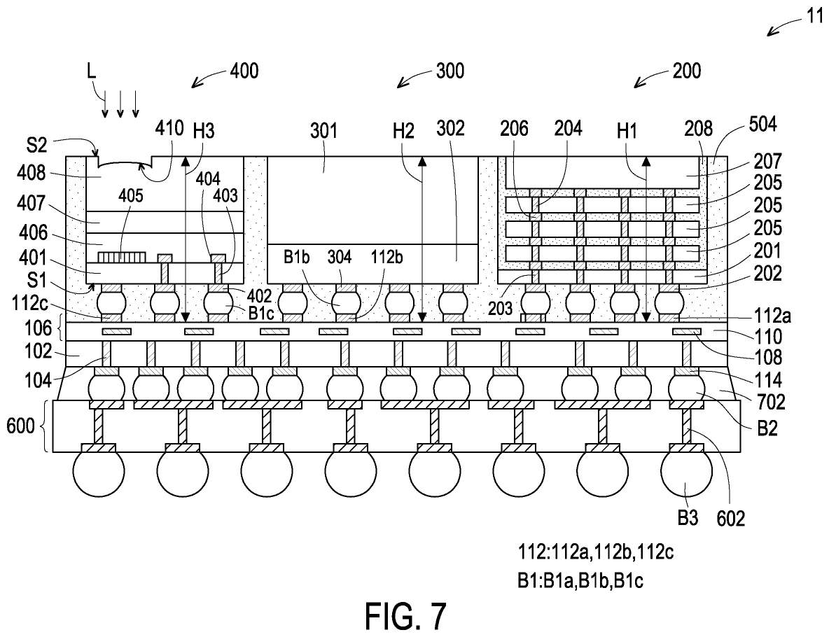

FIG. 7 illustrates a semiconductor package in accordance with some embodiments. The forming method of the semiconductor package 11 of FIG. 7 is similar to the forming method of the semiconductor package 10 of FIG. 6, and the difference between them lies in that, the formation of the underfill layer 502 is omitted from FIG. 2, so the resulting semiconductor package 11 is free of the underfill layer 502. Specifically, the encapsulation layer 504 of the semiconductor package 11 is formed over the interposer structure 100 and laterally encapsulating the sidewalls of the integrated circuit structures 200, 300 and the photonic structure 400. Besides, the encapsulating layer 504 of the semiconductor package 11 fills the space between the interposer structure 100 and each of the integrated circuit structures 200, 300 and the photonic structure 400, and completely fills the gap between the integrated circuit structures 200 and 300 and the gap between the integrated circuit structure 300 and the photonic structure 400.

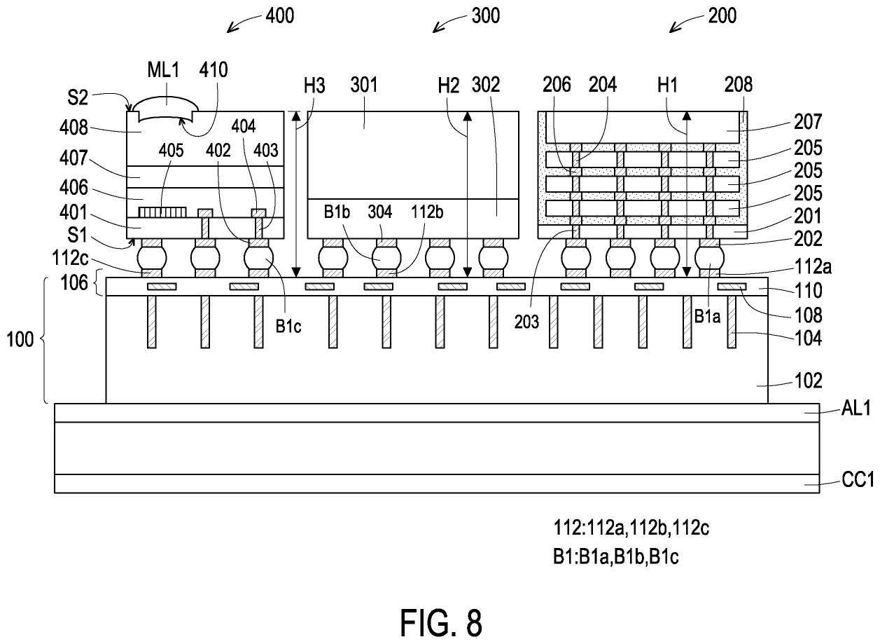

The above embodiments of FIGS. 1-7 in which the mask layer is completely removed from the recessed feature of the photonic structure is provided for illustration purposes, and are not construed as limiting the present disclosure. In other embodiments, the mask layer may remain in the recessed feature of the photonic structure as a protection layer, as shown in FIG. 8 to FIG. 14.

FIG. 8 to FIG. 14 are schematic cross-sectional views of a method of forming a semiconductor package in accordance with some embodiments. It is understood that the disclosure is not limited by the method described below. Additional operations can be provided before, during, and/or after the method and some of the operations described below can be replaced or eliminated, for additional embodiments of the methods. Although FIG. 8 to FIG. 14 are described in relation to a method, it is appreciated that the structures disclosed in FIG. 8 to FIG. 14 are not limited to such a method, but instead may stand alone as structures independent of the method.

The forming method of FIG. 8 to FIG. 14 is similar to the forming method of FIG. 1 to FIG. 7, so the difference between them is described below, and the similarity is not iterated herein. Through the specification, similar components are labelled as similar reference numerals, so the materials, configurations and/or forming methods may refer to those described in above embodiments.

Referring to FIG. 8, an interposer structure 100 is attached to a carrier CC1 through an adhesive layer AL1. Thereafter, at least one integrated circuit structure and a photonic structure is provided and bonded to the interposer structure 100.

In some embodiments, an integrated circuit structure 200 is provided and bonded to the interposer structure 100. The integrated circuit structure 200 may be a memory device such as a dynamic random-access memory (DRAM), a synchronous dynamic random-access memory (SDRAM), a die stack such as a high bandwidth memory (HBM) cube, or the like.

In some embodiments, an integrated circuit structure 300 is provided and bonded to the interposer structure 100. The integrated circuit structure 300 may be a system device such as application-specific integrated circuit (ASIC), a field programmable gate array (FPGA), a central processing unit (CPU) die, a graphics processing unit (GPU) die, an artificial intelligence (AI) engine die, a transceiver (TRX) die, or the like.

In some embodiments, a photonic structure 400 is provided and bonded to the interposer structure 100. In some embodiments, the photonic structure includes a first substrate 401 and a second substrate 408 bonded to each other through a first passivation layers 406 and a second passivation layer 407. The photonic structure 400 has a surface S1 facing the interposer structure 100 and an opposite face S2 facing away the interposer substrate 100. In some embodiments, the first substrate 401 of the photonic structure 400 includes an integrated optical device 405 such as a grating coupler or a waveguide coupler. The grating coupler is configured to enable communication between a light source and another component (e.g., photo-detector). For example, an optical grating coupler can be used to redirect light from an optical fiber into an optical detector.

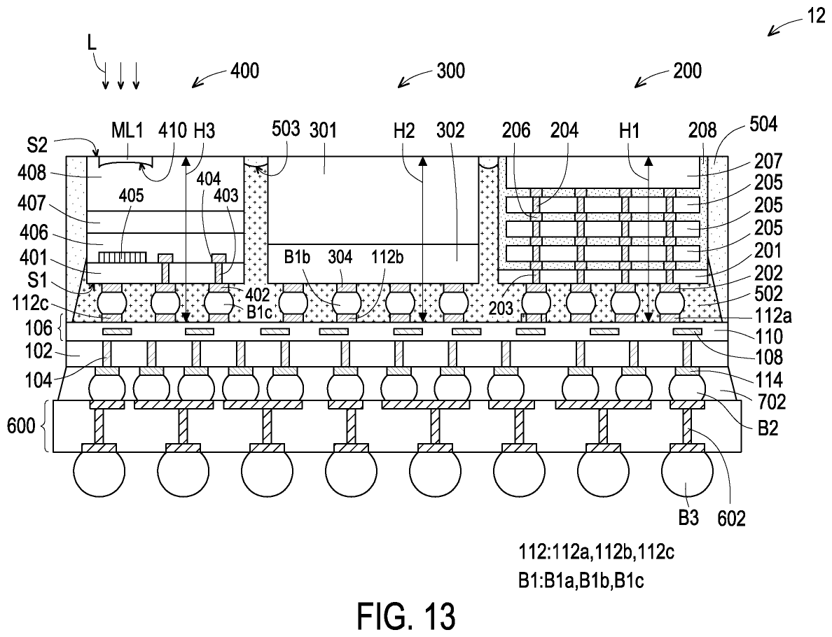

In some embodiments, the second substrate 408 of the photonic structure 400 includes a recessed feature 410 at the surface S2 thereof, and the recessed feature 410 faces a light source (as shown in FIG. 13). The recessed feature 410 may be an optical recessed lens, for example. The recessed feature 410 may be designed to have desired curvature for focusing the light beam to the underlying integrated optical device 405. In some embodiments, the recessed feature 410 is aligned with the underlying integrated optical device 405, but the disclosure is not limited thereto. In other embodiments, the recessed feature 410 may be misaligned with or partially overlapped with the underlying integrated optical device 405.

Still referring to FIG. 8, the recessed feature 410 is covered and protected by a mask layer ML1 at this stage, and the mask layer ML is partially removed in the later stage, which will be described in details below. In some embodiments, the mask layer ML1 includes a transparent material having a transmission percentage of about 80-99% (e.g., 85-95% or 88-92%). Such transparent material is configured to protect the recessed feature 410 and allow the light beam to penetrate therethrough. In some embodiments, the mask layer ML1 may include an optical liquid silicone rubber, poly(methyl methacrylate) (PMMA), an optical epoxy, the like, or a combination thereof. In some embodiments, the mask layer ML1 includes a high numerical aperture (NA) material having a NA of about 0.2 to 0.5. In some embodiments, the mask layer ML1 is formed using dispensing, injecting, and/or spraying process. The mask layer ML1 may have a curve and convex surface. In some embodiments, the mask layer ML1 may cover a portion of the surface S2 of the photonic device 400 and fills the recessed feature 410.

In some embodiments, as shown in FIG. 8, the height H3 of the photonic structure is substantially the same as the height H1 of the integrated circuit structure 200 or the height H2 of the integrated circuit structure, counting from the surface of the interposer structure 100. However, the disclosure is not limited thereto. In other embodiments, the height H3 of the photonic structure may be different from (e.g., less than) the height H1 of the integrated circuit structure 200 or the height H2 of the integrated circuit structure, counting from the surface of the interposer structure 100.

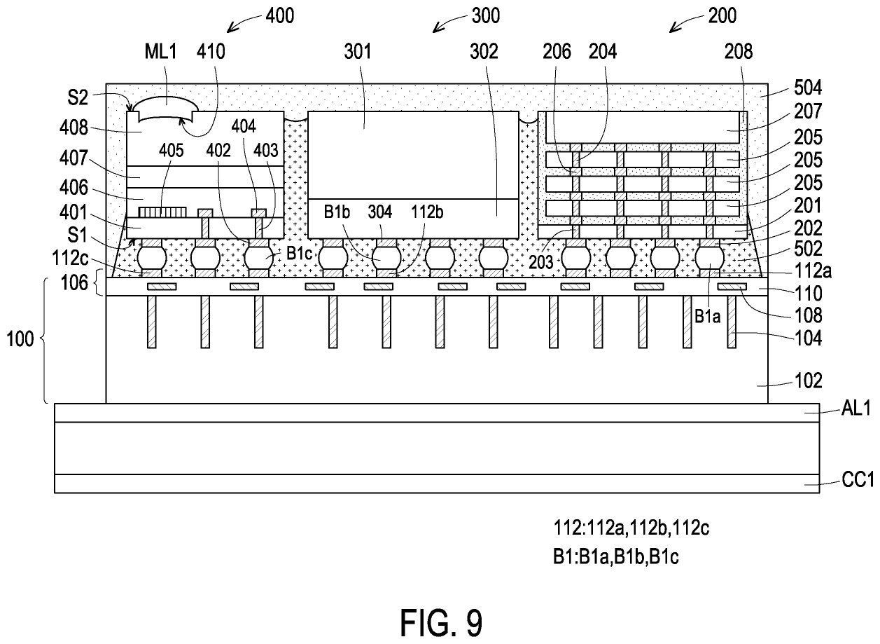

Referring to FIG. 9, an underfill layer 502 is formed to fill the space between the interposer structure 100 and each of the integrated circuit structures 200, 300 and the photonic structure 400, and surrounds the bumps B1 including bumps B1a, B1b and B1c. Thereafter, an encapsulation layer 504 is formed over the interposer structure 100 and covers the integrated circuit structures 200, 300 and the photonic structure 400. Specifically, the encapsulation layer 504 is formed over the underfill layer 502, covers tops of the integrated circuit structures 200, 300, encapsulates the sidewalls (uncover by the underfill layer 502) of the integrated circuit structures 200, 300 and the photonic structure 400, and covers the exposed surface of the mask layer ML1.

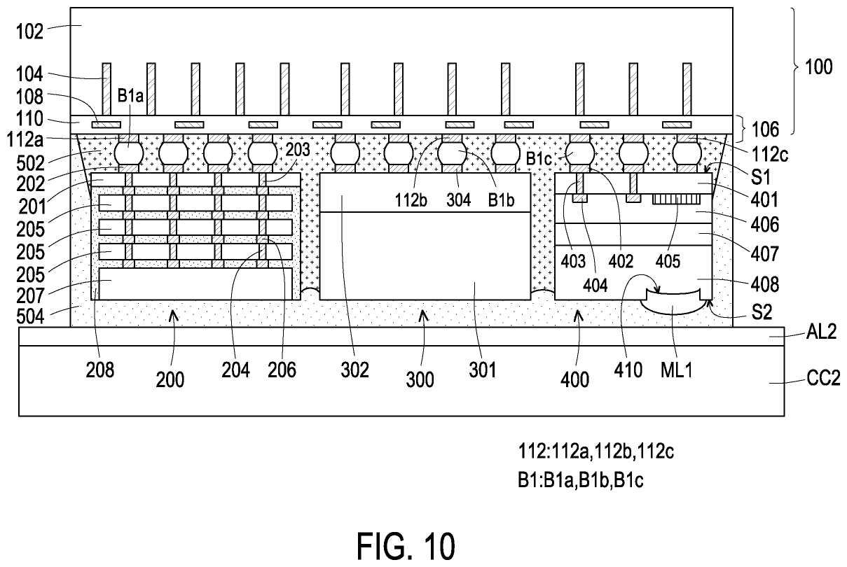

Referring to FIG. 10, a carrier CC2 is attached to the encapsulation layer 504 through an adhesive layer AL2. Thereafter, the structure with the carrier CC2 is flipped over, and the carrier CC1 and the adhesive layer AL1 are debonded from the structure.

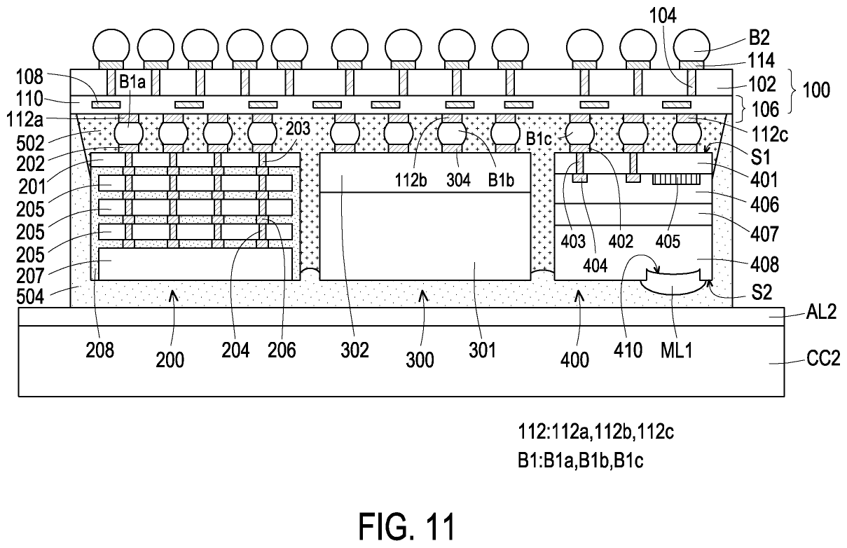

Referring to FIG. 11, a polishing process is performed to the interposer structure 100, until the through substrate vias 104 are exposed. In some embodiments, metal pads 114 (or called under ball metallizaton pads) are formed over and electrically connected to the through substrate vias 104. Afterwards, bumps B2 are formed over and electrically connected to the metal pads 114.

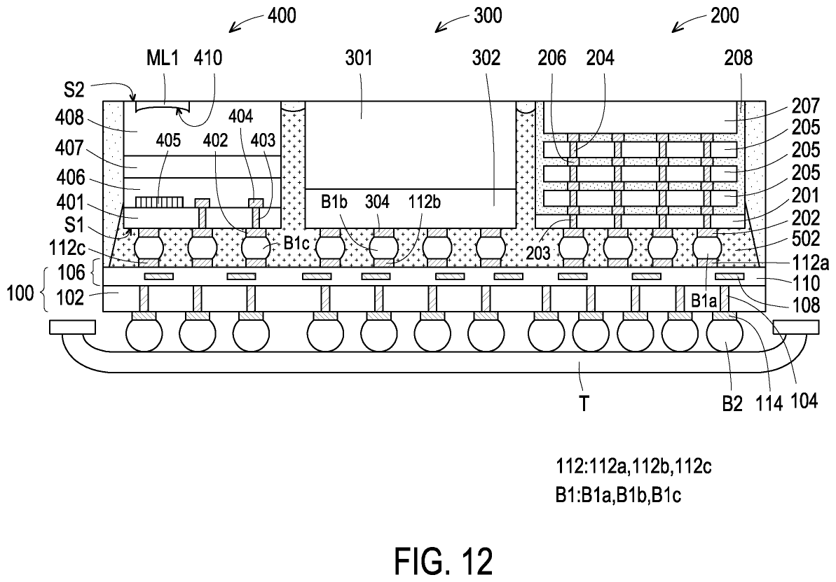

Referring to FIG. 12, the structure of FIG. 11 is flipped over and attached to a wafer tape T, with the bumps B2 facing the wafer tape T. Thereafter, the carrier CC2 and the adhesive layer AL2 are debonded from the encapsulation layer 504.

Afterwards, a grinding process is performed to the encapsulation layer 504. In some embodiments, the grinding process further partially removes the mask layer ML1, until the surface S2 of photonic device 400 is exposed. In some embodiments, upon the grinding process, the top surface of the encapsulation layer 504 is substantially coplanar with or flushed with the top surface of the remaining mask layer ML1 as well as the top surfaces of the integrated circuit structures 200, 300 and the photonic structure 400. The transparent mask layer ML1 remains in the recessed feature 410 as a protection layer.

Referring to FIG. 13, the wafer tape T is removed, and a board substrate 600 is formed below and electrically connected to the interposer structure 100 through the bumps B2. Thereafter, bumps B3 are formed below and electrically connected to the board substrate 600. In some embodiments, the semiconductor package 12 of the disclosure is thus completed. With the method of the disclosure, a photonic device and other system and memory devices can be easily integrated together in a wafer level platform. With optical interconnection provided by the photonic structure, higher communication performance and more compact packaging can be easily achieved.

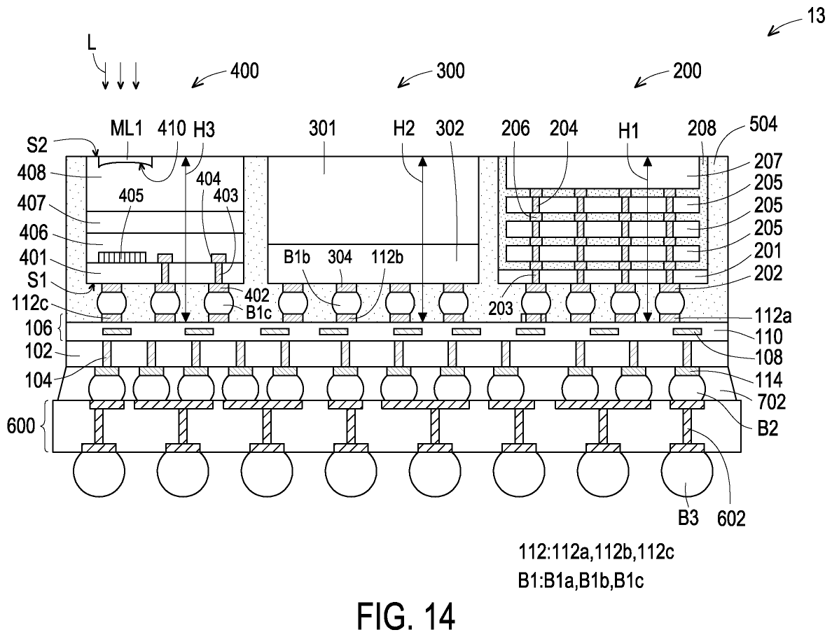

FIG. 14 illustrates a semiconductor package in accordance with some embodiments. The forming method of the semiconductor package 13 of FIG. 14 is similar to the forming method of the semiconductor package 12 of FIG. FIG. 13, and the difference between them lies in that, the formation of the underfill layer 502 is omitted from FIG. 9, so the resulting semiconductor package 13 is free of the underfill layer 502.

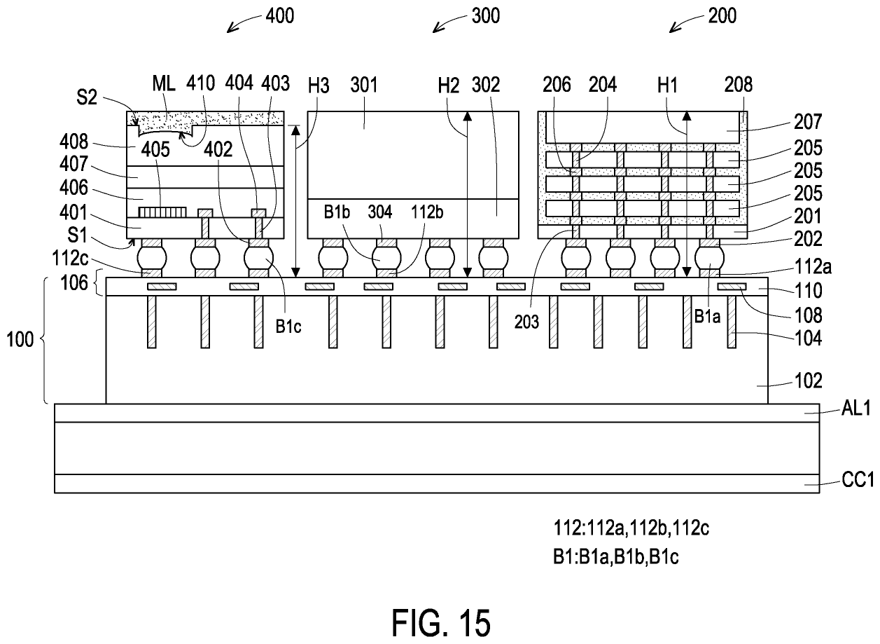

In the above embodiments of FIGS. 1-14, the height H3 of the photonic structure is substantially the same as the height H1 of the integrated circuit structure 200 or the height H2 of the integrated circuit structure, counting from the surface of the interposer structure 100. However, the disclosure is not limited thereto. In other embodiments, the height H3 of the photonic structure may be different from (e.g., less than) the height H1 of the integrated circuit structure 200 or the height H2 of the integrated circuit structure, counting from the surface of the interposer structure 100, as shown in FIG. 15 to FIG. 21.

FIG. 15 to FIG. 21 are schematic cross-sectional views of a method of forming a semiconductor package in accordance with some embodiments. It is understood that the disclosure is not limited by the method described below. Additional operations can be provided before, during, and/or after the method and some of the operations described below can be replaced or eliminated, for additional embodiments of the methods. Although FIG. 15 to FIG. 21 are described in relation to a method, it is appreciated that the structures disclosed in FIG. 15 to FIG. 21 are not limited to such a method, but instead may stand alone as structures independent of the method.

The forming method of FIG. 15 to FIG. 21 is similar to the forming method of FIG. 1 to FIG. 7, so the difference between them is described below, and the similarity is not iterated herein. Through the specification, similar components are labelled as similar reference numerals, so the materials, configurations and/or forming methods may refer to those described in above embodiments.

Referring to FIG. 15, an interposer structure 100 is attached to a carrier CC1 through an adhesive layer AL1. Thereafter, at least one integrated circuit structure and a photonic structure is provided and bonded to the interposer structure 100.

In some embodiments, an integrated circuit structure 200 is provided and bonded to the interposer structure 100. The integrated circuit structure 200 may be a memory device such as a dynamic random-access memory (DRAM), a synchronous dynamic random-access memory (SDRAM), a die stack such as a high bandwidth memory (HBM) cube, or the like.

In some embodiments, an integrated circuit structure 300 is provided and bonded to the interposer structure 100. The integrated circuit structure 300 may be a system device such as application-specific integrated circuit (ASIC), a field programmable gate array (FPGA), a central processing unit (CPU) die, a graphics processing unit (GPU) die, an artificial intelligence (AI) engine die, a transceiver (TRX) die, or the like.

In some embodiments, a photonic structure 400 is provided and bonded to the interposer structure 100. In some embodiments, the photonic structure includes a first substrate 401 and a second substrate 408 bonded to each other through a first passivation layers 406 and a second passivation layer 407. The photonic structure 400 has a surface S1 facing the interposer structure 100 and an opposite face S2 facing away the interposer substrate 100. In some embodiments, the first substrate 401 of the photonic structure 400 includes an integrated optical device 405 such as a grating coupler or a waveguide coupler. The grating coupler is configured to enable communication between a light source and another component (e.g., photo-detector). For example, an optical grating coupler can be used to redirect light from an optical fiber into an optical detector.

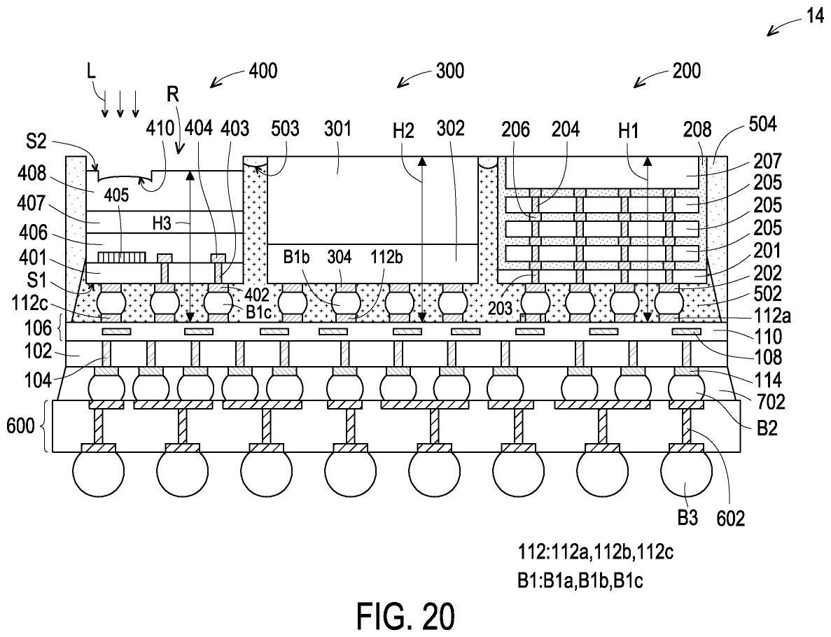

In some embodiments, the second substrate 408 of the photonic structure 400 includes a recessed feature 410 at the surface S2 thereof, and the recessed feature 410 faces a light source (as shown in FIG. 20). The recessed feature 410 may be an optical recessed lens, for example. The recessed feature 410 may be designed to have desired curvature for focusing the light beam to the underlying integrated optical device 405. In some embodiments, the recessed feature 410 is aligned with the underlying integrated optical device 405, but the disclosure is not limited thereto. In other embodiments, the recessed feature 410 may be misaligned with or partially overlapped with the underlying integrated optical device 405.

Still referring to FIG. 15, the recessed feature 410 is covered and protected by a mask layer ML at this stage, and the mask layer ML is completely removed in the later stage, which will be described in details below.

The mask layer ML includes any removable material, and such removable material may be transparent, translucent or opaque. In some embodiments, the mask layer ML includes a dielectric layer, a polymer layer, a molding compound or the like. The mask layer ML may be subjected to a planarization, so as to have a planar surface. In some embodiments, the mask layer ML covers the entire surface S2 of the photonic device 400 and fills the recessed feature 410.

In some embodiments, as shown in FIG. 15, the height H3 of the photonic structure 400 is different from (e.g., less than) the height H1 of the integrated circuit structure 200 or the height H2 of the integrated circuit structure, counting from the surface of the interposer structure 100.

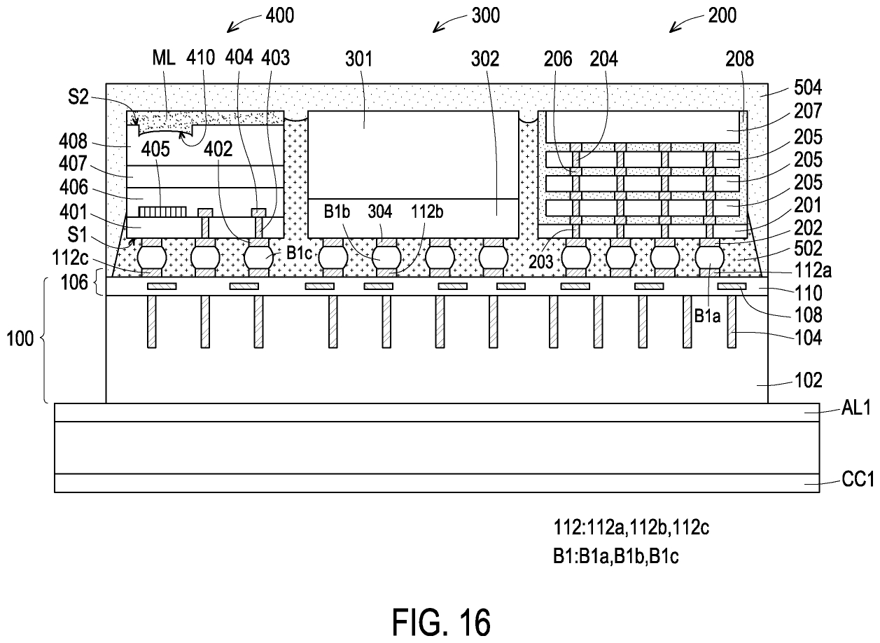

Referring to FIG. 16, an underfill layer 502 is formed to fill the space between the interposer structure 100 and each of the integrated circuit structures 200, 300 and the photonic structure 400, and surrounds the bumps B1 including bumps B1a, B1b and B1c. In some embodiments, the underfill layer 502 is in contact with the mask layer ML. However, the disclosure is not limited thereto. In other embodiments, the underfill layer 502 is separated from the mask layer ML but in contact with the second substrate 408 of the photonic structure 400.

Thereafter, an encapsulation layer 504 is formed over the interposer structure 100 and covers the integrated circuit structures 200, 300 and the photonic structure 400. Specifically, the encapsulation layer 504 is formed over the underfill layer 502, covers tops of the integrated circuit structures 200, 300, encapsulates the sidewalls (uncover by the underfill layer 502) of the integrated circuit structures 200, 300 and the photonic structure 400, and covers the exposed surface of the mask layer ML.

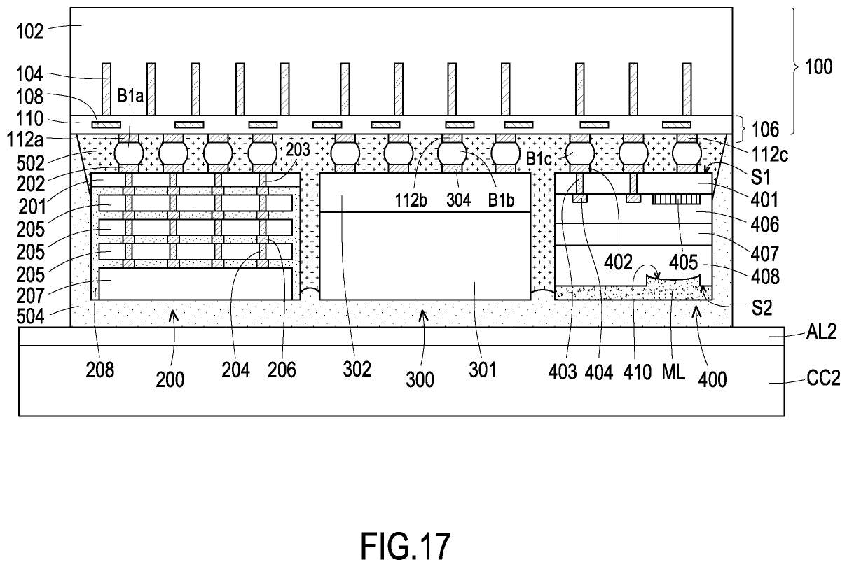

Referring to FIG. 17, a carrier CC2 is attached to the encapsulation layer 504 through an adhesive layer AL2. Thereafter, the structure with the carrier CC2 is flipped over, and the carrier CC1 and the adhesive layer AL1 are debonded from the structure.

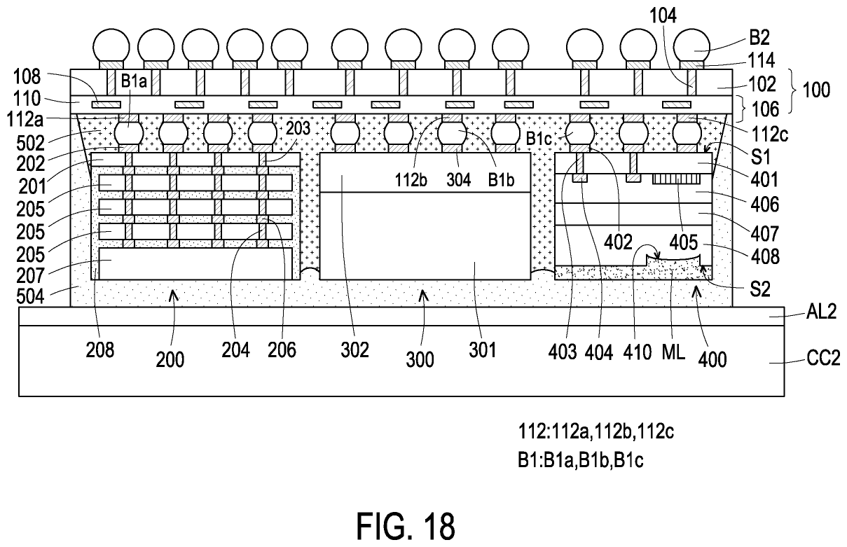

Referring to FIG. 18, a polishing process is performed to the interposer structure 100, until the through substrate vias 104 are exposed. In some embodiments, metal pads 114 (or called under ball metallizaton pads) are formed over and electrically connected to the through substrate vias 104. Afterwards, bumps B2 are formed over and electrically connected to the metal pads 114.

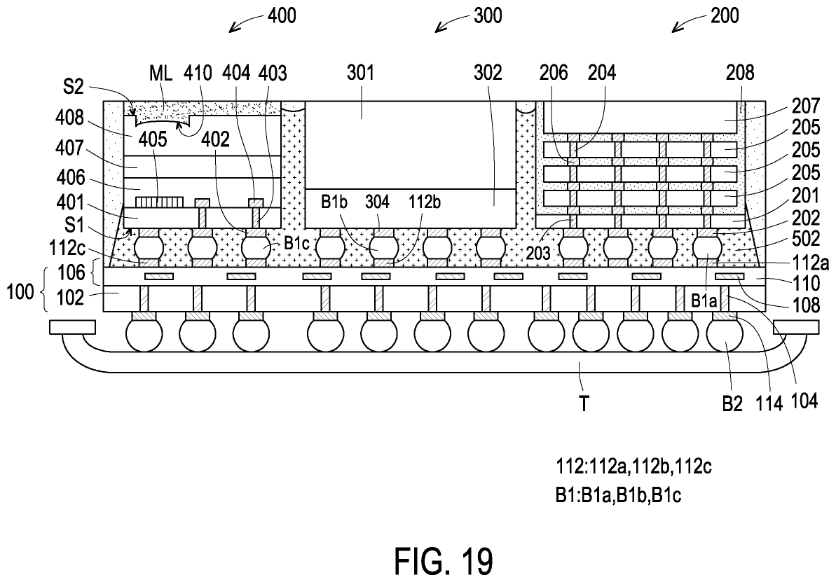

Referring to FIG. 19, the structure of FIG. 18 is flipped over and attached to a wafer tape T, with the bumps B2 facing the wafer tape T. Thereafter, the carrier CC2 and the adhesive layer AL2 are debonded from the encapsulation layer 504.

Afterwards, a grinding process is performed to the encapsulation layer 504. In some embodiments, the grinding process is performed, until the surface of the integrated circuit structure 200 or 300 is exposed. In some embodiments, upon the grinding process, the top surface of the encapsulation layer 504 is substantially coplanar with or flushed with the top surface of the integrated circuit structure 200 or 300.

Referring to FIG. 20, the mask layer ML is removed from the recessed feature 410 of the photonic structure 400. In some embodiments, the mask layer ML is completely removed by an etching process, a plasma process, a laser process, the like, or a combination thereof. Upon the removing process, the recessed feature 410 as an optical recessed lens is exposed to the external environment, facing to a light source L. Upon the removing process, a recess R is provided on top of the photonic structure 400 and encompassed by the surface S2 of the photonic structure 400, the surface of the recessed feature 410, and the sidewall of the encapsulation layer 504.

Thereafter, the wafer tape T is removed, and a board substrate 600 is formed below and electrically connected to the interposer structure 100 through the bumps B2. Thereafter, bumps B3 are formed below and electrically connected to the board substrate 600. In some embodiments, the semiconductor package 14 of the disclosure is thus completed. With the method of the disclosure, a photonic device and other system and memory devices can be easily integrated together in a wafer level platform. With optical interconnection provided by the photonic structure, higher communication performance and more compact packaging can be easily achieved.

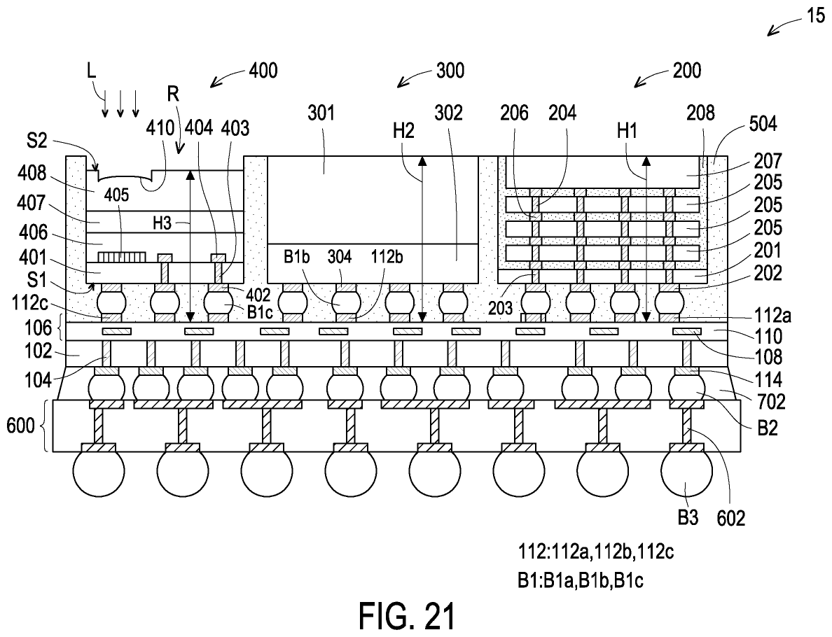

FIG. 21 illustrates a semiconductor package in accordance with some embodiments. The forming method of the semiconductor package 15 of FIG. 21 is similar to the forming method of the semiconductor package 14 of FIG. FIG. 20, and the difference between them lies in that, the formation of the underfill layer 502 is omitted from FIG. 16, so the resulting semiconductor package 15 is free of the underfill layer 502.

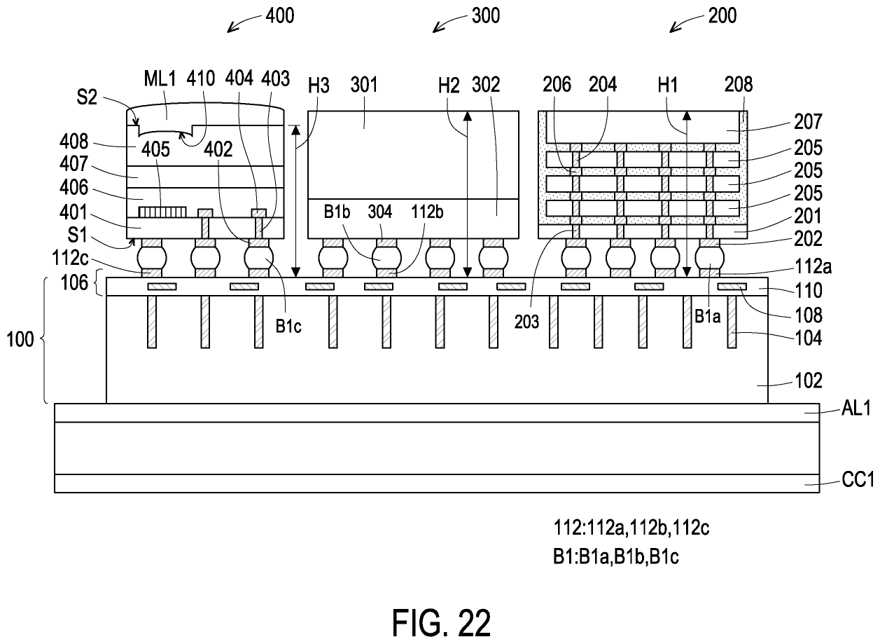

The above embodiments of FIGS. 15-21 in which the mask layer is completely removed from the recessed feature of the photonic structure is provided for illustration purposes, and are not construed as limiting the present disclosure. In other embodiments, the mask layer may remain in the recessed feature of the photonic structure as a protection layer, as shown in FIG. 22 to FIG. 28.

FIG. 22 to FIG. 28 are schematic cross-sectional views of a method of forming a semiconductor package in accordance with some embodiments. It is understood that the disclosure is not limited by the method described below. Additional operations can be provided before, during, and/or after the method and some of the operations described below can be replaced or eliminated, for additional embodiments of the methods. Although FIG. 22 to FIG. 28 are described in relation to a method, it is appreciated that the structures disclosed in FIG. 22 to FIG. 28 are not limited to such a method, but instead may stand alone as structures independent of the method.

Referring to FIG. 22, an interposer structure 100 is attached to a carrier CC1 through an adhesive layer AL1. Thereafter, at least one integrated circuit structure and a photonic structure is provided and bonded to the interposer structure 100.

In some embodiments, an integrated circuit structure 200 is provided and bonded to the interposer structure 100. The integrated circuit structure 200 may be a memory device such as a dynamic random-access memory (DRAM), a synchronous dynamic random-access memory (SDRAM), a die stack such as a high bandwidth memory (HBM) cube, or the like.

In some embodiments, an integrated circuit structure 300 is provided and bonded to the interposer structure 100. The integrated circuit structure 300 may be a system device such as application-specific integrated circuit (ASIC), a field programmable gate array (FPGA), a central processing unit (CPU) die, a graphics processing unit (GPU) die, an artificial intelligence (AI) engine die, a transceiver (TRX) die, or the like.

In some embodiments, a photonic structure 400 is provided and bonded to the interposer structure 100. In some embodiments, the photonic structure includes a first substrate 401 and a second substrate 408 bonded to each other through a first passivation layers 406 and a second passivation layer 407. The photonic structure 400 has a surface S1 facing the interposer structure 100 and an opposite face S2 facing away the interposer substrate 100. In some embodiments, the first substrate 401 of the photonic structure 400 includes an integrated optical device 405 such as a grating coupler or a waveguide coupler. The grating coupler is configured to enable communication between a light source and another component (e.g., photo-detector). For example, an optical grating coupler can be used to redirect light from an optical fiber into an optical detector.

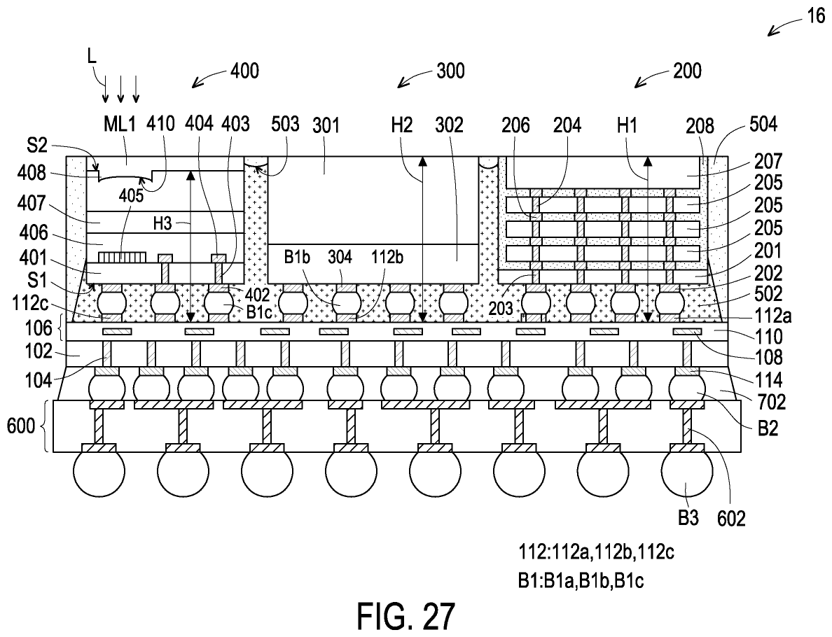

In some embodiments, the second substrate 408 of the photonic structure 400 includes a recessed feature 410 at the surface S2 thereof, and the recessed feature 410 faces a light source (as shown in FIG. 27). The recessed feature 410 may be an optical recessed lens, for example. The recessed feature 410 may be designed to have desired curvature for focusing the light beam to the underlying integrated optical device 405. In some embodiments, the recessed feature 410 is aligned with the underlying integrated optical device 405, but the disclosure is not limited thereto. In other embodiments, the recessed feature 410 may be misaligned with or partially overlapped with the underlying integrated optical device 405.

Still referring to FIG. 22, the recessed feature 410 is covered and protected by a mask layer ML1 at this stage, and the mask layer ML is partially removed in the later stage, which will be described in details below. In some embodiments, the mask layer ML1 includes a transparent material having a transmission percentage of about 80-99% (e.g., 85-95% or 88-92%). Such transparent material is configured to protect the recessed feature 410 and allow the light beam to penetrate therethrough. In some embodiments, the mask layer ML1 may include an optical liquid silicone rubber, poly(methyl methacrylate) (PMMA), an optical epoxy, the like, or a combination thereof. In some embodiments, the mask layer ML1 includes a high numerical aperture (NA) material having a NA of about 0.2 to 0.5. In some embodiments, the mask layer ML1 is formed using dispensing, injecting, and/or spraying process. The mask layer ML1 may have a curve and convex surface. In some embodiments, the mask layer ML1 may cover the entire surface S2 of the photonic device 400 and fills the recessed feature 410.

In some embodiments, as shown in FIG. 22, the height H3 of the photonic structure may be different from (e.g., less than) the height H1 of the integrated circuit structure 200 or the height H2 of the integrated circuit structure, counting from the surface of the interposer structure 100.

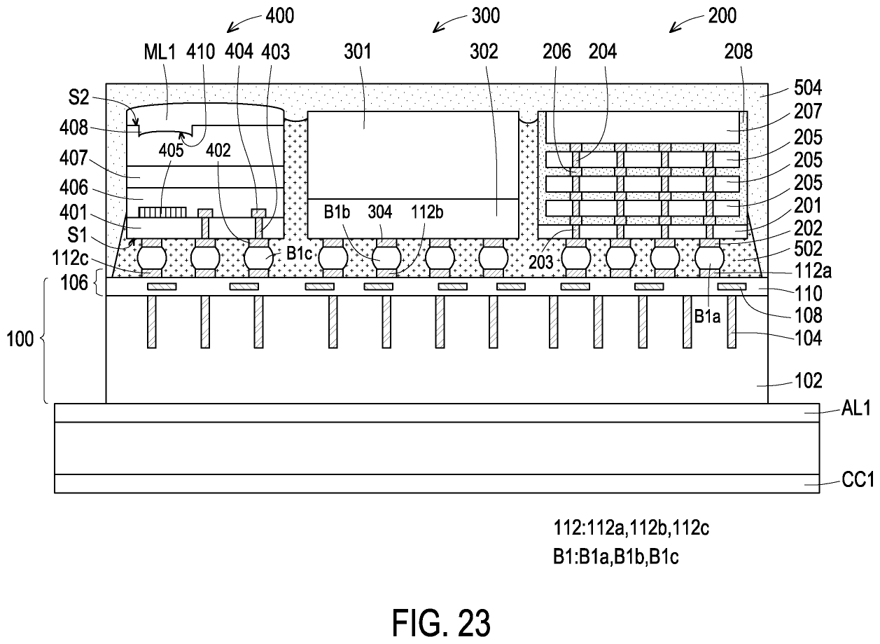

Referring to FIG. 23, an underfill layer 502 is formed to fill the space between the interposer structure 100 and each of the integrated circuit structures 200, 300 and the photonic structure 400, and surrounds the bumps B1 including bumps B1a, B1b and B1c. Thereafter, an encapsulation layer 504 is formed over the interposer structure 100 and covers the integrated circuit structures 200, 300 and the photonic structure 400. Specifically, the encapsulation layer 504 is formed over the underfill layer 502, covers tops of the integrated circuit structures 200, 300, encapsulates the sidewalls (uncover by the underfill layer 502) of the integrated circuit structures 200, 300 and the photonic structure 400, and covers the exposed surface of the mask layer ML1.

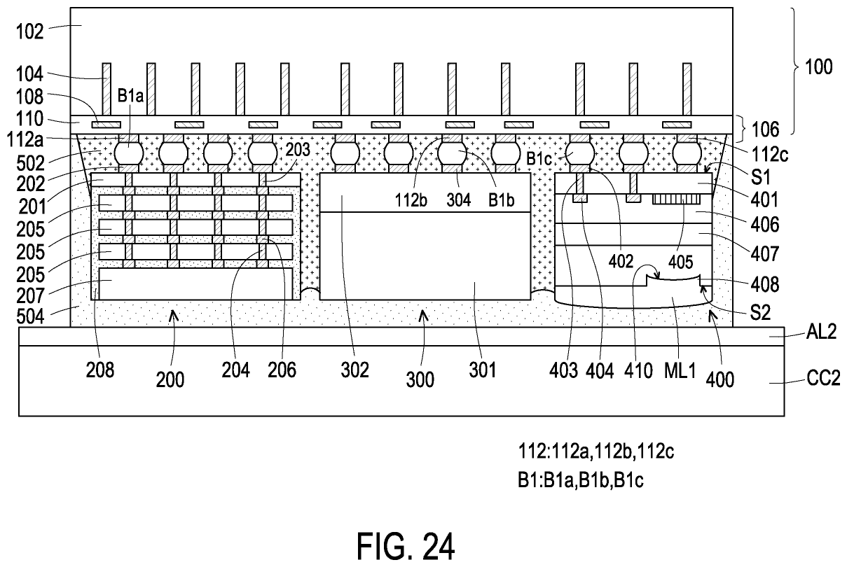

Referring to FIG. 24, a carrier CC2 is attached to the encapsulation layer 504 through an adhesive layer AL2. Thereafter, the structure with the carrier CC2 is flipped over, and the carrier CC1 and the adhesive layer AL1 are debonded from the structure.

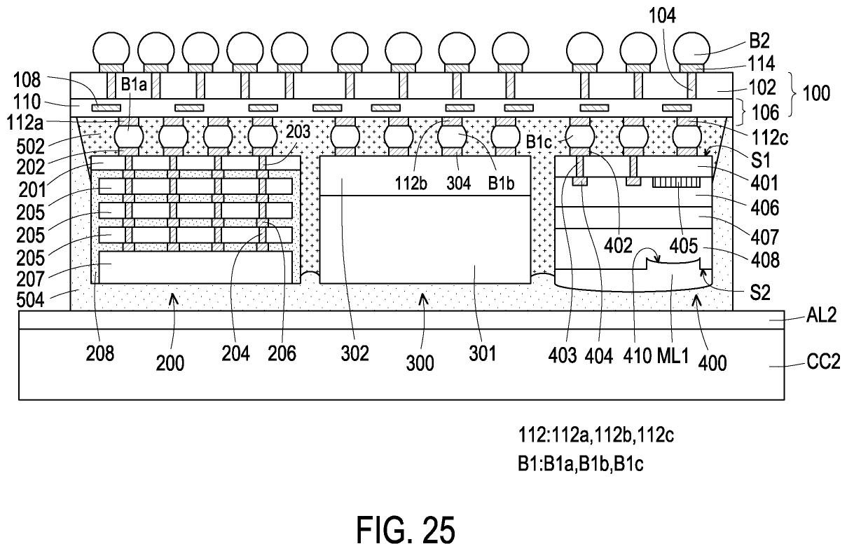

Referring to FIG. 25, a polishing process is performed to the interposer structure 100, until the through substrate vias 104 are exposed. In some embodiments, metal pads 114 (or called under ball metallizaton pads) are formed over and electrically connected to the through substrate vias 104. Afterwards, bumps B2 are formed over and electrically connected to the metal pads 114.

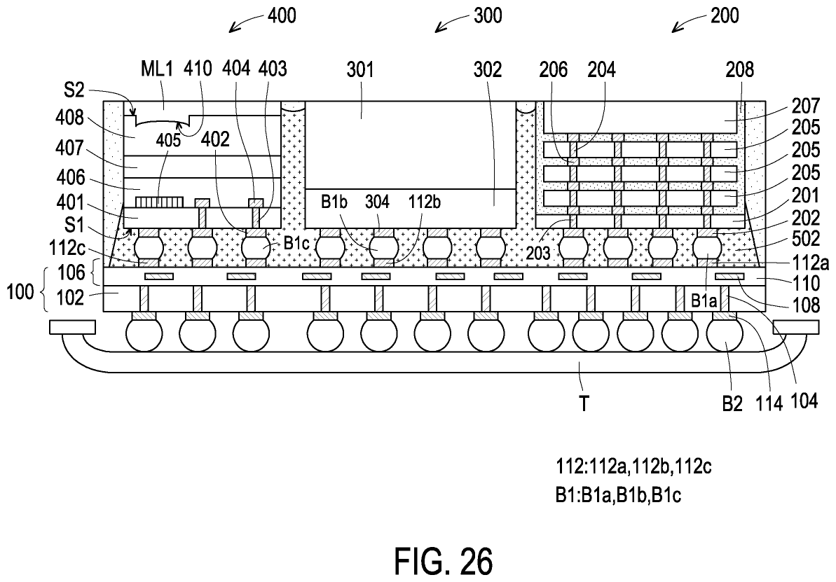

Referring to FIG. 26, the structure of FIG. 25 is flipped over and attached to a wafer tape T, with the bumps B2 facing the wafer tape T. Thereafter, the carrier CC2 and the adhesive layer AL2 are debonded from the encapsulation layer 504.

Afterwards, a grinding process is performed to the encapsulation layer 504. In some embodiments, the grinding process further partially removes the mask layer ML1, until the top surfaces of the integrated circuit structures 200 and 300 are exposed. In some embodiments, upon the grinding process, the top surface of the encapsulation layer 504 is substantially coplanar with or flushed with the top surface of the remaining mask layer ML1 as well as the top surfaces of the integrated circuit structures 200, 300. The top surface of the encapsulation layer 504 is higher than the top surface S2 of the photonic structure 400. The transparent mask layer ML1 remains in the recessed feature 410 as a protection layer.

Referring to FIG. 27, the wafer tape T is removed, and a board substrate 600 is formed below and electrically connected to the interposer structure 100 through the bumps B2. Thereafter, bumps B3 are formed below and electrically connected to the board substrate 600. In some embodiments, the semiconductor package 16 of the disclosure is thus completed. With the method of the disclosure, a photonic device and other system and memory devices can be easily integrated together in a wafer level platform. With optical interconnection provided by the photonic structure, higher communication performance and more compact packaging can be easily achieved.

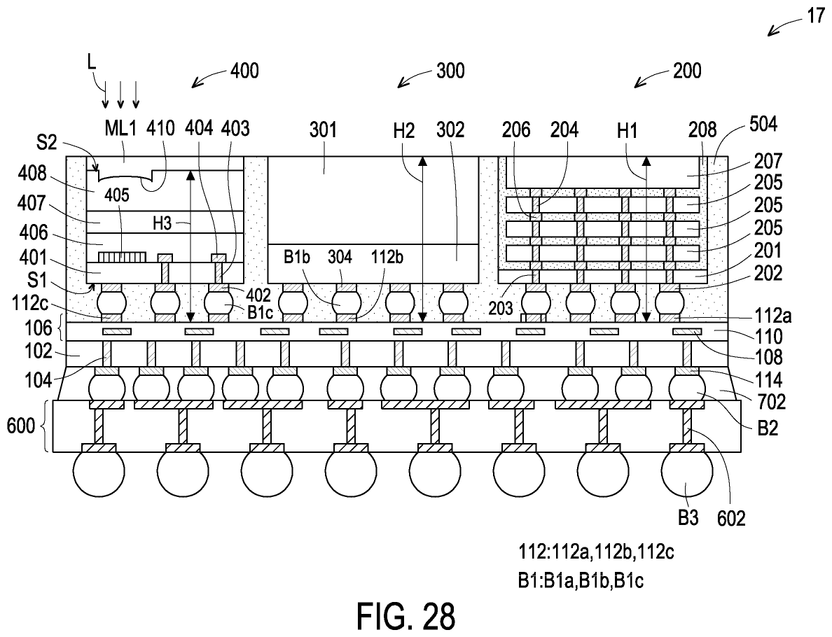

FIG. 28 illustrates a semiconductor package in accordance with some embodiments. The forming method of the semiconductor package 17 of FIG. 28 is similar to the forming method of the semiconductor package 16 of FIG. FIG. 27, and the difference between them lies in that, the formation of the underfill layer 502 is omitted from FIG. 23, so the resulting semiconductor package 17 is free of the underfill layer 502.

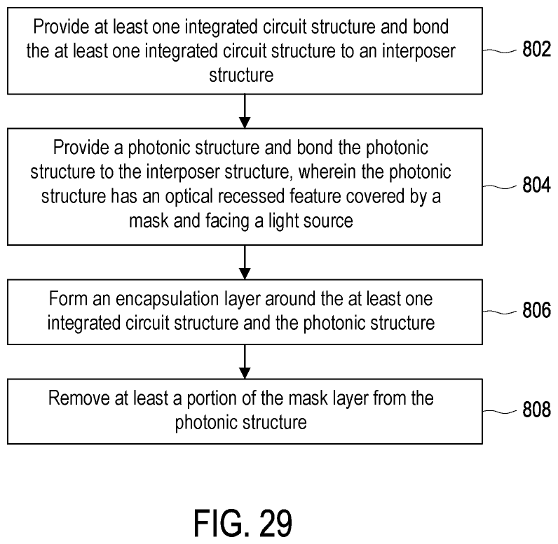

FIG. 29 illustrates a method of forming a semiconductor package in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 802, at least one integrated circuit structure is provided and bonded to an interposer structure. FIG. 1, FIG. 8, FIG. 15 and FIG. 22 illustrate cross-sectional views corresponding to some embodiments of act 802.

At act 804, a photonic structure is provided and bonded to the interposer structure, wherein the photonic structure has a recessed feature covered by a mask and facing a light source. In some embodiments, the photonic structure includes a first substrate bonded to a second substrate, the first substrate faces the interposer structure, and the recessed feature is provided at a surface of the second substrate facing away the interposer structure. In some embodiments, the first substrate is bonded to the second substrate through a first passivation layer and a second passivation layer, respectively, and an optical coupler is embedded in the first passivation layer. FIG. 1, FIG. 8, FIG. 15 and FIG. 22 illustrate cross-sectional views corresponding to some embodiments of act 804.

At act 806, an encapsulation layer is formed around the at least one integrated circuit structure and the photonic structure. In some embodiments, after forming the encapsulation layer, the interposer structure is thinned until surfaces of through substrate vias within the interposer structure are exposed. FIGS. 2-4, FIGS. 9-11, FIGS. 16-18 and FIGS. 23-25 illustrate cross-sectional views corresponding to some embodiments of act 806.

At act 808, at least a portion of the mask layer is removed from the photonic structure. In some embodiments, the mask layer is completely removed from the photonic structure. In some embodiments, the mask layer is partially removed from the photonic structure, and the remaining mask layer remains in the recessed feature. In some embodiments, a top surface of the remaining mask layer is flushed with a top surface of the photonic structure. In some embodiments, a top surface of the remaining mask layer is higher than a top surface of the photonic structure. FIGS. 5-6, FIGS. 12-13, FIGS. 19-20 and FIGS. 26-27 illustrate cross-sectional views corresponding to some embodiments of act 808.

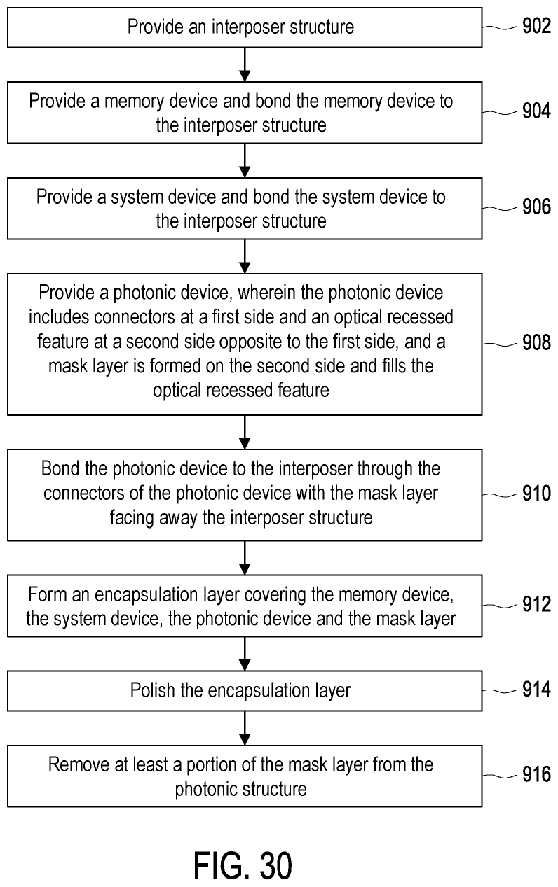

FIG. 30 illustrates a method of forming a semiconductor package in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 902. an interposer structure is provided. FIG. 1, FIG. 8, FIG. 15 and FIG. 22 illustrate cross-sectional views corresponding to some embodiments of act 902.

At act 904. a memory device is provided and bonded to the interposer structure. FIG. 1, FIG. 8, FIG. 15 and FIG. 22 illustrate cross-sectional views corresponding to some embodiments of act 904.

At act 906, a system device is provided and bonded the interposer structure. FIG. 1 FIG. 8, FIG. 15 and FIG. 22 illustrate cross-sectional views corresponding to some embodiments of act 906.

At act 908, a photonic device is provided, wherein the photonic device includes connectors at a first side and a recessed feature at a second side opposite to the first side, and a mask layer is formed on the second side and fills the recessed feature.

At act 910, the photonic device is bonded to the interposer through the connectors of the photonic device with the mask layer facing away the interposer structure. FIG. 1, FIG. 8, FIG. 15 and FIG. 22 illustrate cross-sectional views corresponding to some embodiments of act 910.

At act 912, an encapsulation layer is formed to cover the memory device, the system device, the photonic device and the mask layer. FIG. 2, FIG. 9, FIG. 16 and FIG. 23 illustrate cross-sectional views corresponding to some embodiments of act 912.

At 914, the encapsulation layer is polished. FIGS. 3-4, FIGS. 10-11, FIGS. 17-18 and FIGS. 24-25 illustrate cross-sectional views corresponding to some embodiments of act 914.

At act 916, at least a portion of the mask layer is removed from the photonic structure. In some embodiments, the mask layer is completely removed. In some embodiments, the mask layer is partially removed. In some embodiments, a height of the photonic device is substantially the same as a height of the memory device or the system device. In some embodiments, a height of the photonic device is less than a height of the memory device or the system device. FIGS. 5-6, FIGS. 12-13, FIGS. 19-20 and FIGS. 26-27 illustrate cross-sectional views corresponding to some embodiments of act 916.

The semiconductor packages of the disclosure are illustrated below with reference to FIG. 1 to FIG. 28.

In some embodiments, a semiconductor package 10/11/12/13/14/15/16/17 includes an interposer structure 100, at least one integrated circuit structure 200/300, a photonic structure 400 and an encapsulation layer 504. The at least one integrated circuit structure 200/300 is disposed on the interposer structure 100. The photonic structure 400 is disposed on the interposer structure 100 and aside the at least one integrated circuit structure 200/300, wherein the photonic structure 400 has a recessed feature 410 at a top surface S2 thereof. The encapsulation layer 504 is disposed around the at least one integrated circuit structure 200/300 and the photonic structure 400, wherein the recessed feature 410 of the photonic structure 400 is free of the encapsulation layer 504.

In some embodiments, the semiconductor package 12/13/16/17 further includes a mask layer ML1 in the recessed feature 410. In some embodiments, the mask layer ML1 includes a transparent material.

In some embodiments, a top surface of the mask layer ML1 is flushed with a top surface of the encapsulation layer 504, as shown in FIGS. 13-14 and 27-28. In some embodiments, a top surface of the mask layer ML1 is flushed a top surface of the photonic structure 400, as shown in FIGS. 13-14. In some embodiments, a top surface of the mask layer ML1 is higher than a top surface of the photonic structure 400, as shown in FIGS. 27-28.

In some embodiments, the photonic structure 400 includes a first substrate 401 bonded to a second substrate 408, the first substrate 401 faces the interposer structure 100, and the recessed feature 410 is provided at a surface of the second substrate 408 facing away the interposer structure 100. In some embodiments, the first substrate 401 is bonded to the second substrate 408 through a first passivation layer 406 and a second passivation layer 107, respectively, and an optical coupler 405 is embedded in the first passivation layer 406.

In view of the foregoing, embodiments described herein disclose semiconductor packages such as photonic-electric integrated circuit (IC) packages. With the method of the disclosure, a photonic device and other system and memory devices can be easily integrated together in a wafer level platform. With optical interconnection provided by the photonic structure, higher communication performance and more compact packaging can be easily achieved.

Many variations of the above examples are contemplated by the present disclosure. It is understood that different embodiments may have different advantages, and that no particular advantage is necessarily required of all embodiments.

In accordance with some embodiments of the present disclosure, a semiconductor package includes the following operations. At least one integrated circuit structure is provided and bonded to an interposer structure. A photonic structure is provided and bonded to the interposer structure, wherein the photonic structure has a recessed feature covered by a mask and facing a light source. An encapsulation layer is formed around the at least one integrated circuit structure and the photonic structure. At least a portion of the mask layer is removed from the photonic structure.

In accordance with alternative embodiments of the present disclosure, a method of forming a semiconductor package includes following operations. An interposer structure is provided. A memory device is provided and bonded to the interposer structure. A system device is provided and bonded the interposer structure. A photonic device is provided, wherein the photonic device includes connectors at a first side and a recessed feature at a second side opposite to the first side, and a mask layer is formed on the second side and fills the recessed feature. The photonic device is bonded to the interposer through the connectors of the photonic device with the mask layer facing away the interposer structure. An encapsulation layer is formed to cover the memory device, the system device, the photonic device and the mask layer. The encapsulation layer is polished.

In accordance with yet alternative embodiments of the present disclosure, a semiconductor package includes an interposer structure, at least one integrated circuit structure, a photonic structure and an encapsulation layer. The at least one integrated circuit structure is disposed on the interposer structure. The photonic structure is disposed on the interposer structure and aside the at least one integrated circuit structure, wherein the photonic structure has a recessed feature at a top surface thereof. The encapsulation layer is disposed around the at least one integrated circuit structure and the photonic structure, wherein the recessed feature of the photonic structure is free of the encapsulation layer.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer structure;
at least one integrated circuit structure disposed over the interposer structure;
a photonic structure disposed over the interposer structure and aside the at least one integrated circuit structure, wherein the photonic structure has a recessed feature at a top surface thereof; and
an encapsulation layer disposed around the at least one integrated circuit structure and the photonic structure.

2. The semiconductor package of claim 1, wherein the recessed feature of the photonic structure is free of the encapsulation layer.

3. The semiconductor package of claim 1, further comprising a mask layer in the recessed feature.

4. The semiconductor package of claim 3, wherein the mask layer comprises a transparent material.

5. The semiconductor package of claim 2, wherein a top surface of the mask layer is flushed with a top surface of the encapsulation layer.

6. The semiconductor package of claim 2, wherein a top surface of the mask layer is higher than a top surface of the photonic structure.

7. The semiconductor package of claim 1, wherein the photonic structure comprises a first substrate bonded to a second substrate, the first substrate faces the interposer structure, and the recessed feature is at a surface of the second substrate facing away the interposer structure.

8. A method of forming a semiconductor package, comprising:
bonding a photonic structure to an interposer structure, wherein a top surface of the photonic structure has a recess covered by a mask layer;
forming an encapsulation layer around the photonic structure; and
removing the mask layer to expose the recess.

9. The method of claim 8, wherein the recess has a substantially vertical sidewall and a convex bottom, and is configured to focus a light beam to an optical device in the photonic structure.

10. The method of claim 8, wherein the removing the mask layer comprises:
forming the encapsulation layer to cover the top surface of the photonic structure and the mask layer in the recess;
performing a planarization process on the encapsulation layer to expose the top surface of the photonic structure, wherein a top surface of the encapsulation layer, a top surface of the mask layer, and the top surface of the photonic structure are substantially coplanar with each other; and
completely removing the mask layer.

11. The method of claim 8, wherein the photonic structure comprises a first substrate bonded to a second substrate, the first substrate faces the interposer structure, and the recess is provided at a surface of the second substrate facing away the interposer structure.

12. The method of claim 11, wherein the first substrate is bonded to the second substrate through a first passivation layer and a second passivation layer, respectively, and an optical coupler is embedded in the first passivation layer.

13. The method of claim 8, further comprising:
bonding at least one integrated circuit structure to the interposer structure; and
forming an underfill layer between the at least one integrated circuit structure and the interposer structure, between the photonic structure and the interposer structure, and between the photonic structure and the at least one integrated circuit structure before forming the encapsulation layer, wherein the encapsulation layer laterally encapsulates the underfill layer.

14. The method of claim 8, further comprising, after forming the encapsulation layer,
thinning the interposer structure until surfaces of through substrate vias within the interposer structure are exposed.

15. A semiconductor package, comprising:
an interposer structure;
a photonic structure disposed over the interposer structure, wherein the photonic structure comprises a first substrate bonded to a second substrate, the first substrate faces the interposer structure, and the second substrate has a recess concave from a top surface of photonic structure toward the interposer structure; and
an encapsulation layer laterally encapsulating the photonic structure.

16. The semiconductor package of claim 15, wherein the recess is free of the encapsulation layer.

17. The semiconductor package of claim 15, wherein the recess has a substantially vertical sidewall and a convex bottom, and is configured to focus a light beam to an optical device in the photonic structure.

18. The semiconductor package of claim 15, further comprising:
at least one integrated circuit structure disposed over the interposer structure; and
an underfill layer disposed between the at least one integrated circuit structure and the interposer structure, between the photonic structure and the interposer structure, and between the photonic structure and the at least one integrated circuit structure, wherein the encapsulation layer laterally encapsulates the underfill layer.

19. The semiconductor package of claim 18, wherein the encapsulation layer interfaces a top surface of the underfill layer between the photonic structure and the interposer structure, and the top surface of the underfill layer is a curved top surface.

20. The semiconductor package of claim 15, wherein the first substrate is bonded to the second substrate through a first passivation layer and a second passivation layer, respectively, and an optical coupler is embedded in the first passivation layer.
